(19) United States
(12) Patent Application Publication
(10) Pub. No.: US 2006/0121365 A1
(43) Pub. Date: Jun. 8, 2006

(54) Mask and exposure device

(75) Inventors: Gerhard Kunkel, Radebeul (DE); Ralf Winkler, Radebeul (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/295,691

(22) Filed: Dec. 7, 2005

(30) Foreign Application Priority Data
Dec. 7, 2004 (DE) 10 2004 058 813.9

(51) Int. Cl. G03C 5/00; G03F 1/00

(52) U.S. Cl. 430/5; 430/394; 430/322

(57) ABSTRACT

In the case of a mask having a structure which can be imaged on a substrate lithographically at a predetermined exposure wavelength and has at least one structure element with a width in the same order of magnitude as the exposure wavelength, the structure element is subdivided into sections which are separated from one another and whose length is in the same order of magnitude as the exposure wavelength.

### CLAIM FOR PRIORITY

This application claims the benefit of priority to German Application No. 10 2004 058 813.9 filed Dec. 7, 2004.

### TECHNICAL FIELD OF THE INVENTION

The invention relates to a mask and to an exposure device for exposure of a photoresist layer on a substrate having a mask.

### BACKGROUND OF THE INVENTION

Integrated circuits, in particular semiconductor memories, are generally produced on semiconductor substrates by means of the planar technique. This planar technique includes a sequence of individual processes each of which acts over the entire area of the substrate surface and which deliberately lead to local changes in the semiconductor material via suitable masking layers.

In this case, the lithographic technique is used virtually all the time for structuring of the semiconductor substrates. The major feature of this technique is a photoresist which is sensitive to radiation, is applied to the semiconductor substrate and is illuminated in the desired areas such that only the illuminated or unilluminated areas are removed in a suitable developer. The photoresist pattern produced in this way then acts as a mask for a subsequent process step, for example for etching or for ion implantation. The photoresist mask is then dissolved again.

In the course of lithography, the object of the exposure method is to image the desired structures on the surface of the photoresist layer. For this purpose, the structure to be produced is generally first of all created in an enlarged form on an imaging mask (reticle). In order to structure the semiconductor substrate, the reticle is then introduced into the beam path of an optical system, generally a projection exposure device, by means of which the structure which has been created on the reticle is transferred on a reduced scale, for example with a size ratio of 4:1, to the photoresist layer on the semiconductor substrate. Since the entire substrate surface generally cannot be exposed simultaneously owing to the restricted field of view of the high-resolution optics, the structure is imaged a plurality of times successively on the substrate surface using the step-and-repeat process.

The aim of the exposure methods is to achieve as high a resolution as possible in order to make it possible to create even very small structures on the photoresist layer, and thus on the semiconductor substrate. One possible way to miniaturize structures on semiconductor substrates is to enlarge the numerical aperture of the projection exposure device. The numerical aperture of the exposure device is in this case proportional to the sine of the beam angle of the beam from the light source of the exposure device which strikes the wafer. The wider the beam angle and thus the incidence angle of the electromagnetic radiation, the greater is the resolution capability.

Furthermore, sufficiently high contrast between exposed points and unexposed points is required for reliable imaging of the reticle structure on a photoresist layer. This contrast is in this case influenced by the reflection and transmission processes on and in the mask and by the chemical reactions when the electromagnetic radiation strikes the photoresist. These processes are in turn influenced by the polarization direction of the electromagnetic radiation. The unpolarized electromagnetic radiation which is generally used for a projection exposure device can be split into a transverse magnetic component and a transverse electrical component. The transverse magnetic component and the transverse electrical component of the electromagnetic radiation in this case make different contributions to the light/dark contrast on the photoresist, depending on the numerical aperture of the exposure device.

This is because the transverse electrical component of the electromagnetic radiation can always interfere completely irrespective of the numerical aperture and can thus cause optimal contrast, since the electrical field vectors of the transverse electrical component of the radiation are oriented not only at right angles to the incidence plane of the radiation but also at right angles to the propagation direction, and they are hence always oriented parallel to one another, irrespective of the incidence angle. The electrical field vectors of the transverse magnetic component of the electromagnetic radiation are, in contrast, oriented on the incidence plane of the radiation, and are oriented at right angles to the propagation direction. If light is incident obliquely, that is to say the numerical aperture is large, the electrical field vectors of the electromagnetic radiation can then no longer interfere completely with one another, and this leads to a deterioration of the contrast between exposed and unexposed points on the photoresist.

Greater contrast, caused by the transverse electrical component, or reduced contrast, caused by the transverse magnetic component, is thus achieved depending on the ratio of the transverse electrical component to the transverse magnetic component of the electromagnetic radiation. In the case of the unpolarized electromagnetic radiation which is generally used in projection exposure devices, the proportions of the transverse electrical component and of the transverse magnetic component are the same, so that the resultant contrast is an average of the contrast produced by the two polarization components.

In order to allow ever smaller structures to be produced in the course of progressive miniaturization, however, masks with structure elements whose width is in the same order of magnitude as the exposure wavelength are also increasingly being produced for high-resolution, reduced-size projection exposure. In particular, in this case, reticles with line gratings act as a polarization filter, with the transverse electrical component which increases the contrast being attenuated, and with its proportion in the electromagnetic radiation thus being reduced. This then leads to a reduced light/dark contrast on the photoresist and thus to a deterioration in the resolution capability of the system to be imaged.

### SUMMARY OF THE INVENTION

The invention relates to a mask having a structure which can be imaged on a substrate lithographically at a predetermined exposure wavelength and has at least one structure element with a width in the same order of magnitude as the exposure wavelength, and to an exposure device for exposure of a photoresist layer on a substrate having a mask such as this.

The present invention also provides a mask and an exposure device by means of which higher optical quality, in particular contrast, is achieved in the lithographic exposure of photoresist.

According to one embodiment of the invention, in the case of a mask having a structure which can be imaged on a substrate lithographically at a predetermined exposure wavelength and has at least one structure element with a width in the same order of magnitude as the exposure wavelength, the structure element is subdivided into sections which are separated from one another and whose length is in the same order of magnitude as the exposure wavelength. This mask design prevents an electrical field vector, which is aligned parallel to the structure element, of the transverse electrical component of the exposure radiation from being absorbed. The subdivision of the structure element into small areas with a length dimension in the same order of magnitude as the exposure wavelength prevents dichroitic polarization from occurring. This therefore ensures that the transverse electrical component of the electromagnetic radiation, which is advantageous for the light/dark contrast, is deflected from the mask onto the photoresist located on the semiconductor substrate.

According to one preferred embodiment, the structure element on the mask is a periodic line arrangement with the lines being subdivided into regularly arranged sections which are separated from one another and whose length is in the same order of magnitude as the exposure wavelength. This design prevents line structures, in particular such as those which are required to form components for the purposes of semiconductor memories, acting as polarization filters on the mask. The interruption of the line structures prevents the electrical field vector of the transverse electrical component of the electromagnetic radiation from oscillating parallel to the line structure, and in the process stimulating, and thus absorbing, charge carriers in the line structure.

According to a further preferred embodiment, the distance between the sections of the structure element is less by a factor of at least 2 than the exposure wavelength. This prevents the individual sections of the structure element from being resolved on the photoresist during the exposure process, which would lead to imaging errors.

According to a further preferred embodiment, the structure element is applied as a raised structure element on a mount, with the separation between the sections of the structure element being produced by an interruptions in the structure element. This procedure allows simple structuring of the mask in conventional reticle production techniques. The resultant structure element on the mask can be formed on the mount by lithography. The subdivision of the structure element can be carried out subsequently, for example by means of an etching step. Alternatively, it is possible, instead of producing an interruption in the structure element, to change the material characteristics in the structure element between the sections in order to form the separation areas in this way. A change such as this in the material characteristics, which ensures that the oscillation of charge carriers, stimulated by the electrical field vector of the transverse electrical component of the electromagnetic radiation, in the structure element can be attenuated, for example by subsequent doping in the separation areas or by use of materials with different conductivity at right angles to and parallel to the structure.

The mask according to the invention is preferably used in a projection exposure device, preferably in the form of a chromium on glass reticle.

### BRIEF DESCRIPTION OF THE DRAWINGS

The invention will be explained in more detail below with reference to the exemplary embodiments and attached drawings, in which:

FIG. 1 shows one embodiment of a projection exposure device according to the invention.

FIG. 2 shows a detail of a mask according to the invention with a periodic line structure.

### DETAILED DESCRIPTION OF THE INVENTION

The object of exposure methods in lithography is to create desired brightness structures on the surface of a substrate which is covered with a photoresist in order subsequently to be able to deliberately locally change the substrate by means of the photoresist that has been structured in accordance with the brightness structures and to allow the desired structures to be formed.

A resolution performance which is as high as possible is in this case a critical assessment criterion for the design of the exposure system and for the design of the mask for imaging of the structure on the photoresist. The projection exposure device according to the invention and the associated mask design ensure that the transverse electrical component of the electromagnetic exposure radiation, which amplifies the light/dark contrast, is deflected onto the photoresist.

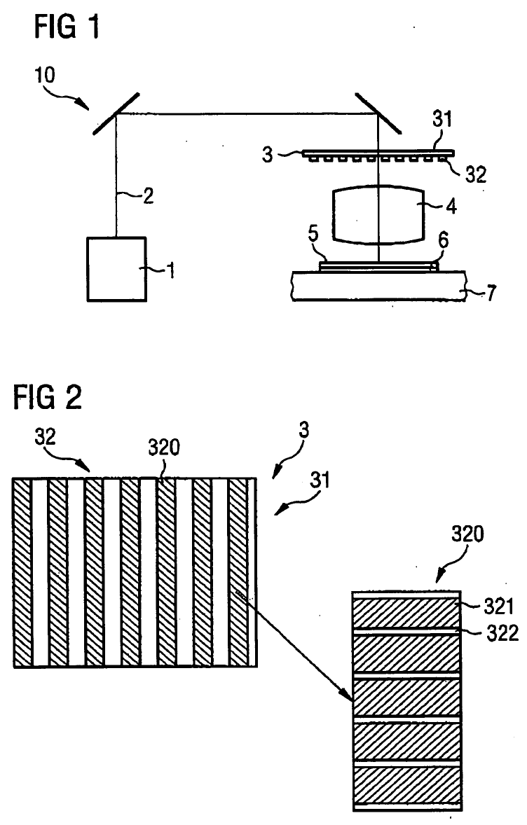

FIG. 1 shows one possible design of a light-optical projection exposure device 10 according to the invention. The projection exposure device 10 is in this case in the form of a wafer stepper in which a pattern which is to be imaged on a photoresist layer 5 of a semiconductor substrate 6 is multiplied by the semiconductor substrate 6 to be exposed being positioned successively such that the pattern can be created on all the desired areas of the photoresist layer 5.

The light-optical wafer stepper has a light source 1, generally a laser, which emits unpolarized light at a predetermined wavelength, for example at 248 nm or 193 nm. The laser light is passed through a beam path 2 with deflection mirrors to a mask 3, which contains a raised pattern 32 of the brightness structure to be produced, on a transparent mount 31. The light which passes through the mask 3 is preferably reduced in size by a high-resolution projection objective 4, for example being projected onto the photoresist layer 5 on the semiconductor substrate 6 with a size ratio of 4:1. The semiconductor substrate 6 is in turn arranged on a movement table 7, whose movement allows the individual image windows to be moved on the semiconductor substrate.

In order to prevent a structure element 320 of a structure 32 that is to be imaged on the substrate 5 and has a width in the same order of magnitude as the exposure wavelength from attenuating the transverse electrical component of the exposure radiation as it passes through the mask 3, the structure element 320 is subdivided into sections 321 which are separated from one another and whose length is in the same order of magnitude as the exposure wavelength.

FIG. 2 shows a plan view of a structure element 320 such as this, which is a periodic line structure, as is used as a pattern during the formation of semiconductor memories. The distance between the grating lines is in this case in the same order of magnitude as the exposure wavelength. In order to prevent the transverse electrical component of the exposure radiation, whose electrical field vectors lie parallel to the grating lines on the mask plane, from causing oscillation of charge carriers, in particular electrons, in the grating lines, and thus being absorbed, each line is subdivided, as is shown in the partial view in FIG. 2, into small, preferably regular sections 321, whose length is in the same order of magnitude as the exposure wavelength. This subdivision prevents the charge carriers in the grating line from being able to be stimulated by the electrical field vector of the transverse electrical component of the exposure radiation that is oriented in the direction of the grating line. No dichroitic polarization therefore occurs, which would result in attenuation of the contrast-increasing transverse electrical component of the electromagnetic radiation.

The distance 322 between the individual sections of the grating line 320 is in this case less than the exposure wavelength by a factor of at least 2, and preferably by a factor of 10, in order to prevent the interruptions in the line structure from also being transferred to the photoresist.

The structure elements 320 to form the pattern on the mask 3 are preferably in the form of a raised structure 32 on a transparent mount 31. For this purpose, a metallic layer, preferably chromium, is applied over the entire surface, as a light-absorbing material, on the transparent mount, preferably a glass or quartz plate. This layer is in turn coated with a photoresist as a radiation-sensitive film. The desired structure elements of a design level are then imaged on the appropriate large scale, depending on the reduction in size that is used, in the resist layer.

This is done by means of the pattern generator. The pattern generator photographically images the desired structure elements by means of mechanical diaphragms and on the desired scale on the quartz plate that is coated with chromium and photoresist. The diaphragms are positioned, computer-controlled by means of a data tape. The exposure takes place by laser flashing. The desired structure is created in the photoresist layer by a large number of repeated positioning and exposure steps. The photoresist is then removed at the illuminated points, and the chromium layer is subjected to wet-chemical etching. Only the structure of a design level of a structure to be formed on the substrate then remains as a chromium absorber on the quartz plate, enlarged by the desired factor.

Alternatively, the mask can also be produced directly by means of an electron beam plotter. The quartz plate is in this case coated with a resist which is sensitive to electron beams. The quartz plate is located together with the electron source and the focusing and deflection unit in a hard vacuum. The finely focused electron beam is scanned over the entire mask under computer control in order to produce the structure, and is keyed to be light and dark by means of a data tape, which contains the mask data. This therefore allows structure widths down to less than 50 nm to be resolved.

The subdivision according to the invention of the structure elements into small sections in the same order of magnitude as the exposure wavelength can also be carried out at the same time as the formation of the individual structure elements. Alternatively, it is possible to subdivide the structures retrospectively into sections, lithographically. Furthermore, the subdivision of the structure elements can also be carried out mechanically or by means of a focused ion beam.

As an alternative to an interruption in the resultant structure elements, it is also possible to subdivide the structure elements into the individual sections by changing the material characteristics in the structure element itself. For this purpose, the separation range between the individual sections can be changed, for example, by means of doping. This doping then ensures that any charge carrier oscillation in the line structure is damped, thus preventing absorption of the electrical field vector of the transverse electrical component of the exposure radiation. Alternatively, it is also possible to use materials with different conductivities at right angles to and parallel to the line structure in order to produce a change in the material characteristics.

According to the invention, deliberate interruption of mask structures to be imaged lithographically ensures that no dichroitic polarization of the exposure radiation is produced by the structure elements of the mask, thus attenuating the transverse electrical polarization component of the radiation which is advantageous for image production on the substrate. This makes it possible to achieve an improved exposure quality.

What is claimed is:

1. A mask, comprising:
a structure configured to be imaged on a substrate lithographically at a predetermined exposure wavelength; and
at least one structure element with a width in a same order of magnitude as the exposure wavelength, wherein the structure element is subdivided into sections which are separated from one another and whose length is in a same order of magnitude as the exposure wavelength.

2. The mask as claimed in claim l, wherein the structure element has a periodic line arrangement, wherein the lines are subdivided into regularly arranged sections which are separated from one another and whose length is in a same order of magnitude as the exposure wavelength.

3. The mask as claimed in claim 1, wherein the distance between the sections of the structure element is less by a factor of at least 2 than the exposure wavelength.

4. The mask as claimed in claim 1, wherein the structure element is applied as a raised structure element on a mount, and the separation between the sections of the structure element is produced by an interruption in the structure element.

5. The mask as claimed in claim 1, wherein the structure element is applied as a raised structure element on a mount, and the separation between the sections of the structure element is produced by changing the material characteristics of the structure element in the areas of separation.

6. The mask as claimed in claim 1, wherein the structure is a chromium structure which is applied to a glass mount.

7. An exposure device for exposure of a photoresist layer on a substrate, comprising:
a light source for emission of radiation at an exposure wavelength;
a mask which has a structure which is configured to be imaged on a substrate lithographically at the predetermined exposure wavelength and has at least one structure element with a width in a same order of magnitude as the exposure wavelength, wherein the structure element is subdivided into sections which are separated from one another and whose length is in a same order of magnitude as the exposure wavelength; and
a projection objective.

8. A mask, comprising a periodic line arrangement which is configured to be imaged on a substrate lithographically at a predetermined exposure wavelength, wherein the distance between grating lines is in a same order of magnitude as the exposure wavelength, wherein the grating lines are each subdivided into sections which are separated from one another and whose length is in a same order of magnitude as the exposure wavelength.

9. The mask as claimed in claim 8, wherein the distance between the sections of the grating line is less by a factor of at least 2 than the exposure wavelength.

10. The mask as claimed in claim 8, wherein the grating line is applied as a raised structure element to a mount, wherein the separation between the sections of the grating line is produced by an interruption in the grating line.

11. The mask as claimed in claim 8, wherein the grating line is applied as a raised structure element to a mount, wherein the separation between the sections of the grating line is produced by changing the material characteristics of the grating line in these separation areas.

12. The mask as claimed in claim 8, wherein the periodic line arrangement is a chromium structure which is applied to a glass mount.

13. An exposure device for exposure of a photoresist layer on a substrate, comprising:
a light source for emission of radiation at an exposure wavelength;
a mask which has a periodic line arrangement configured to be imaged on a substrate lithographically at the predetermined exposure wavelength, wherein the distance between grating lines is in a same order of magnitude as the exposure wavelength, and the grating lines are each subdivided into sections which are separated from one another and whose length is in the same order of magnitude as the exposure wavelength; and
a projection objective.
